(19) United States
(12) Patent Application Publication
(10) Pub. No.: US 2024/0077363 A1
(43) Pub. Date: Mar. 7, 2024

(54) THERMOELECTRIC ELEMENT, METHOD FOR PRODUCING THERMOELECTRIC ELEMENT, THERMOELECTRIC DEVICE, AND METHOD FOR PRODUCING THERMOELECTRIC DEVICE

(71) Applicant: Murata Manufacturing Co., Ltd., Nagaokakyo-shi (JP)

(72) Inventors: Takahiro TAGUCHI, Nagaokakyo-shi (JP); Toru TAKAHASHI, Nagaokakyo-shi (JP)

(21) Appl. No.: 18/503,686

(22) Filed: Nov. 7, 2023

Related U.S. Application Data
(63) Continuation of application No. PCT/JP22/25808, filed on Jun. 28, 2022.

(30) Foreign Application Priority Data
Jun. 30, 2021 (JP) 2021-108584

(51) Int. Cl. G01K 1/16; B22D 11/06

(52) U.S. Cl. CPC G01K 1/16; B22D 11/06

(57) ABSTRACT

A thermoelectric element that contains a plate shaped thermoelectric material that exhibits an anomalous Nernst effect, the thermoelectric element having an average thickness of 10 μm to 100 μm, and an average cross-sectional area of 0.008 mm² to 1 mm² as measured in a cross section perpendicular to the longitudinal direction of the thermoelectric element.

### CROSS REFERENCE TO RELATED APPLICATIONS

The present application is a continuation of International application No. PCT/JP2022/025808, filed Jun. 28, 2022, which claims priority to Japanese Patent Application No. 2021-108584, filed Jun. 30, 2021, the entire contents of each of which are incorporated herein by reference.

### TECHNICAL FIELD

The present invention relates to a thermoelectric element, a method for producing a thermoelectric element, a thermoelectric device, and a method for producing a thermoelectric device.

### BACKGROUND ART

A heat flux sensor in the form of a film is disclosed in Patent Document 1 as an example of a thermoelectric device that converts heat into electricity by using the temperature differences in the material. The heat flux sensor described in Patent Document 1 includes an insulating member, first thermoelectric members, second thermoelectric members, first conductor patterns, and second conductor patterns. The insulating member is in the form of a flexible film and has a first surface and a second surface on opposite sides. The first thermoelectric members are disposed in the insulating member and made of a first thermoelectric material. The second thermoelectric members are disposed in the insulating member and made of a second thermoelectric material different from the first thermoelectric material. The first thermoelectric members and the second thermoelectric members are arranged alternatingly. The first conductor patterns are closer than the first thermoelectric members and the second thermoelectric members to the first surface. Each of the first conductor patterns forms a connection between the corresponding one of the first thermoelectric members and the second thermoelectric member adjacent to the first thermoelectric member. The second conductor patterns are closer than the first thermoelectric members and the second thermoelectric members to the second surface. Each of the second conductor patterns forms a connection between the corresponding one of the first thermoelectric members and the second thermoelectric member adjacent to the first thermoelectric member. The heat flux sensor described in Patent Document 1 further includes an extensible member. The extensible member is higher in extensibility than the insulating member given that a comparison is made between the extensible member and the insulating member that are equal in dimension.
Patent Document 1: Japanese Patent No. 6658572

### SUMMARY OF THE INVENTION

The heat flux sensor described in Patent Document 1 is designed to be placed on a measurement surface of an object subjected to measurement, with the first surface or the second surface brought into contact with the object. A heat flux passes through the heat flux sensor while flowing from one of the first and second surfaces to the other surface. The heat flux causes a temperature difference between the first surface and the second surface of the heat flux sensor. This means a temperature difference between one end and the other end of each of the thermoelectric members (each of the first thermoelectric members and the corresponding one of the second thermoelectric members) connected to each other. As a result, a thermoelectromotive force is generated across the first thermoelectric member and the second thermoelectric member by the Seebeck effect. The thermoelectromotive force or, more specifically, voltage is output as a sensor signal from the heat flux sensor described in Patent Document 1.

The heat flux sensor described in Patent Document 1 is a combination of the insulating member, the first thermoelectric members, the second thermoelectric members, the first conductor patterns, and the second conductor patterns. Such a structure tends to lack flexibility. For this reason, the heat flux sensor described in Patent Document 1 is difficult to handle and susceptible to damage (e.g., wire breakage) during the process of being stuck to a heat source (object) whose radius of curvature is small (e.g., a heating or cooling element that has a thin cylindrical shape). That is, whether the heat flux sensor described in Patent Document 1 can be stuck to an intended heat source depends on the magnitude of the radius of curvature of the heat source.

One conceivable way to improve the ease of sticking the heat flux sensor in Patent Document 1 to a heat source is to reduce the thickness of the heat flux sensor.

Unfortunately, it is not possible to cause a large temperature difference in the heat flux sensor with a reduced thickness. This can lead to a decrease in the thermoelectromotive force of the heat flux sensor in Patent Document 1.

Minimizing the thermal resistance between mating surfaces of the heat flux sensor and the heat source is one of the common approaches to measuring heat flux with a high degree of accuracy. However, it is not possible to completely eliminate the thermal resistance of the extensible member of the heat flux sensor in Patent Document 1.

The present invention therefore has been made to solve the problems described above, and it is an object of the present invention to provide a thermoelectric element that can be stuck to an object with a small radius of curvature and that has a high thermoelectromotive force. It is another object of the present invention to provide a method for producing the thermoelectric element. It is still another object of the present invention to provide a thermoelectric device including the thermoelectric element. It is yet still another object of the present invention to provide a method for producing the thermoelectric device.

A thermoelectric element according to the present invention contains a plate shaped thermoelectric material that exhibits an anomalous Nernst effect, where the thermoelectric element has an average thickness of 10 μm to 100 μm, and an average cross-sectional area of 0.008 mm² to 1 mm² as measured in a cross section perpendicular to a longitudinal direction of the thermoelectric element.

A method for producing a thermoelectric element, the method including: melting a thermoelectric material comprising an intermetallic compound in a receptacle to obtain a molten alloy; and performing a liquid quenching of the molten material by ejecting the molten alloy from the receptacle onto a rotating quenching roller so as to cool and solidify the molten material and form the thermoelectric element having an average thickness of 10 μm to 100 μm, and an average cross-sectional area of 0.008 mm² to 1 mm² as measured in a cross section perpendicular to a longitudinal direction of the thermoelectric element, wherein the liquid quenching is conducted with a Euler (Eu) number in a range of 0.001 to 0.1, the Eu number being given by an expression Eu=ΔP/(ρU²), where ΔP is a pressure of the molten alloy being ejected, ρ is a density (kg/m³) of the molten material, and U is peripheral rotational velocity (m/s) of the quenching roller.

A thermoelectric device according to the present invention includes a heat source and the thermoelectric element according to the present invention wound around the heat source.

A method for producing a thermoelectric device according to the present invention includes: producing the thermoelectric element by the above-noted method; and winding the thermoelectric element around a heat source.

The present invention provides a thermoelectric element that can be stuck to an object with a small radius of curvature and that has a high thermoelectromotive force. The present invention also provides a method for producing the thermoelectric element. The present invention also provides a thermoelectric device including the thermoelectric element. The present invention also provides a method for producing the thermoelectric device.

### BRIEF DESCRIPTION OF THE DRAWINGS

FIG. 1 is an external view photograph of an example of a thermoelectric element (consisting principally of Fe₃Al) according to the present invention.

FIG. 2 is an image of crystal grains in a thermoelectric material contained in an example of the thermoelectric element according to the present invention.

FIG. 3 schematically illustrates an example of how a thermoelectric element is produced by a melt spinning process.

FIG. 4 is a photograph showing an example of how a thermoelectric element (consisting principally of Fe₃Al) is produced by the melt spinning process.

FIG. 5 is a conceptual diagram for explanation of the Euler (Eu) number in the melt spinning process.

### DETAILED DESCRIPTION OF THE PREFERRED EMBODIMENTS

The following describes the present invention relating to a thermoelectric element, a method for producing a thermoelectric element, a thermoelectric device, and a method for producing a thermoelectric device. The following should not be construed as limiting the features of the present invention, which may be modified as appropriate within a range not changing the gist of the present invention. It should be noted that varying combinations of two or more desirable configurations, which will be described below, are also embraced by the present invention.

[Thermoelectric Element]

The thermoelectric element according to the present invention contains a thermoelectric material that exhibits the anomalous Nernst effect. The thermoelectric element is plate-like in shape. The average thickness of the thermoelectric element is 10 μm to 100 μm. The average cross-sectional area of the thermoelectric element is 0.008 mm² to 1 mm² as measured in a cross section perpendicular to the longitudinal direction of the thermoelectric element.

The thermoelectric element according to the present invention contains a thermoelectric material that exhibits the anomalous Nernst effect. To be more specific, the thermoelectric element according to the present invention contains a thermoelectric material that exhibits the magneto-thermoelectric effect induced by the anomalous Nernst effect.

The thermoelectromotive force caused by the anomalous Nernst effect can be expressed by the following expression: V=S_{N}·L·ΔT/t, where V is the thermoelectromotive force, S_{N} is the anomalous Nernst effect coefficient, ΔT is the temperature difference within a thermoelectric element or a thermoelectric device, t is the thickness in a direction parallel to a heat flux generated by the temperature difference within the thermoelectric element or the thermoelectric device, and L is the length in a direction parallel to an electric current caused by the electromotive force of the thermoelectric element or the thermoelectric device.

The thermoelectric material contained in the thermoelectric element according to the present invention consists principally of an intermetallic compound with chemical formula Fe₃Al, Fe₃Ga, Mn₃Sn, Mn₃Ga, Co₂MnGa, Co₂MnAl, Co₂MnIn, Mn₃Ge, Fe₂NiGa, CoTiSb, CoVSb, CoCrSb, CoMnSb, or TiGa₂Mn.

The expression “consisting principally of” is herein used to refer to a component whose weight percentage is higher than that of any other component.

The thermoelectric material contained in the thermoelectric element according to the present invention is preferably in the ordered phase. For example, Fe₃Al and Fe₃Ga each have the DO3 structure, Mn₃Sn has a structure having two layers of kagome lattice in the [0001] direction, Mn₃Ga has the tetragonal D022 structure, and Co₂MnGa is a full Heusler compound in the L21 cubic structure.

The thermoelectric material contained in the thermoelectric element according to the present invention preferably contains an intermetallic compound in the ordered phase.

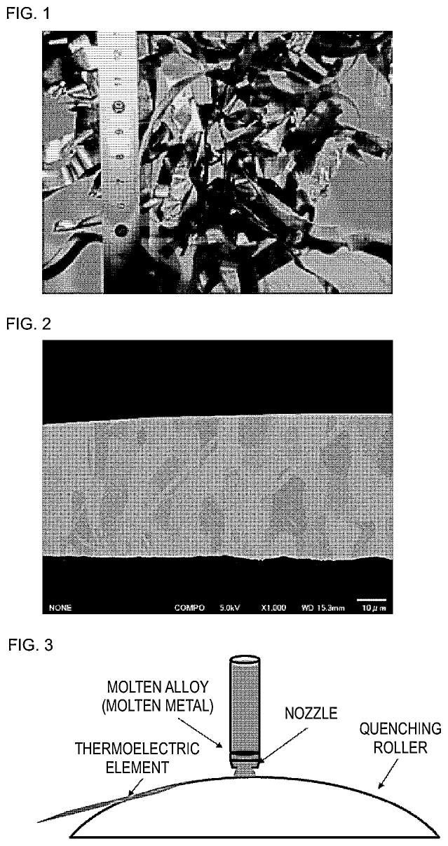

FIG. 1 is an external view photograph of an example of the thermoelectric element (consisting principally of Fe₃Al) according to the present invention.

The thermoelectric material contained in the thermoelectric element according to the present invention may consist principally of a Weyl magnetic substance.

The thermoelectric element according to the present invention is plate-like in shape.

Being plate-like in shape herein may also mean being in the form of a thin strip.

It is preferable that the thermoelectric element according to the present invention be of substantially rectangular cross section perpendicular to the longitudinal direction.

The average thickness of the thermoelectric element according to the present invention is 10 μm to 100 μm.

For example, a thermoelectric element with an average thickness of less than 10 μm is prone to breakage due to the shortage of mechanical strength when being forcibly stuck to an object whose radius of curvature is small. Furthermore, the temperature difference between main surfaces opposite to each other in the thickness direction perpendicular to the longitudinal direction of such a thermoelectric element with an average thickness of less than 10 μm is too small, in which case the temperature gradient between the main surfaces of the thermoelectric element is too small. This leads to a reduction in thermoelectromotive force.

A thermoelectric element with an average thickness of more than 100 μm has an excessively high geometrical moment of inertia and is thus prone to breakage when being forcibly stuck to an object whose radius of curvature is small.

The average cross-sectional area of the thermoelectric element according to the present invention is 0.008 mm² to 1 mm² as measured in a cross section perpendicular to the longitudinal direction of the thermoelectric element.

A thermoelectric element with an average cross-sectional area of less than 0.008 mm² in the direction perpendicular to the longitudinal direction of the thermoelectric element has an excessively high electrical resistance. This leads to a reduction in thermoelectromotive force.

A thermoelectric element with an average cross-sectional area of more than 1 mm² in the direction perpendicular to the longitudinal direction of the thermoelectric element has a high geometrical moment of inertia and is thus prone to breakage when being forcibly stuck to an object whose radius of curvature is small.

The average thickness of the thermoelectric element and the average cross-sectional area in the direction perpendicular to the longitudinal direction of the thermoelectric element are determined by the procedure that will be described later in relation to Examples.

The thermoelectromotive force generated in the thermoelectric element is in proportion to the temperature difference within the thermoelectric element. If the shape and the dimensions such as the thickness of the thermoelectric element are adjusted so that the thermoelectric element can be stuck to an object whose radius of curvature is small, there would be a small temperature difference within the thermoelectric element. Consequently, the thermoelectric element would be more likely to fail to attain a desired level of thermoelectromotive force. The shape and the dimensions such as the thickness of a conventional thermoelectric element designed with a view toward a greater temperature difference within the thermoelectric element are unsuited for the case in which the thermoelectric element is to be stuck to an object whose radius of curvature is small.

As a workaround, the thermoelectric element according to the present invention involves all of the following features: (1) the thermoelectric element is plate-like in shape; (2) the average thickness of the thermoelectric element is 10 μm to 100 μm; and (3) the average cross-sectional area in the direction perpendicular to the longitudinal direction of the thermoelectric element is 0.008 mm² to 1 mm². The thermoelectric element can be stuck to an object whose radius of curvature is small, and the thermoelectric element has a high thermoelectromotive force. More specifically, the present invention provides a thermoelectric element having specific material characteristics with a minimum number of points for connection with electrodes. The thermoelectric element is flexible and is less prone to breakage so that the thermoelectric element can be stuck to an object whose radius of curvature is small. Furthermore, the shape, the thickness, and the cross-sectional area of the thermoelectric element according to the present invention may be adjusted as mentioned above so that the thermoelectric element can obtain a high thermoelectromotive force.

The expression “stuck to” herein may also be used to describe, for example, a state in which an object of interest is wound around another object.

The average crystal grain size of the thermoelectric material contained in the thermoelectric element according to the present invention is preferably 2 μm to 100 μm as measured in the cross section perpendicular to the longitudinal direction of the thermoelectric element.

As can be explained on the basis of the inverse Hall-Petch law, a thermoelectric element containing a thermoelectric material whose average crystal grain size is less than 2 μm as measured in cross sections perpendicular to the longitudinal direction of the thermoelectric element is prone to breakage due to the shortage of toughness when being forcibly stuck to an object whose radius of curvature is small.

A thermoelectric element containing a thermoelectric material whose average crystal grain size is more than 100 μm as measured in cross sections perpendicular to the longitudinal direction of the thermoelectric element has an excessively high thermal conductivity. The temperature difference between main surfaces opposite to each other in the thickness direction of such a thermoelectric element is too small, in which case the temperature gradient between the main surfaces of the thermoelectric element is too small. This can lead to a reduction in thermoelectromotive force.

Given that the average crystal grain size of the thermoelectric material contained in the thermoelectric element according to the present invention is measured in cross sections perpendicular to the longitudinal direction of the thermoelectric element, the average crystal grain size in a region close to one of the main surfaces of the thermoelectric element may be equal to or different from the average crystal grain size in a region close to the other main surface of the thermoelectric element.

The average crystal grain size of the thermoelectric material contained in the thermoelectric element or, more specifically, the average crystal grain size in cross sections perpendicular to the longitudinal direction of the thermoelectric element is determined by the procedure that will be described later in relation to Examples.

The average crystal grain size of the thermoelectric material contained in the thermoelectric element or, more specifically, the average crystal grain size in cross sections perpendicular to the longitudinal direction of the thermoelectric element is measured on the basis of, for example, an image in FIG. 2. FIG. 2 is an image of crystal grains in a thermoelectric material contained in an example of the thermoelectric element according to the present invention.

A thermoelectric element with a smaller minimum bending radius can provide a higher degree of freedom in the design of an object to which the thermoelectric element is to be stuck; that is, a thermoelectric element with a smaller minimum bending radius can be bended to (wound around) objects of various shapes. The minimum bending radius herein refers to the threshold value of the bending radius at which the thermoelectric element according to the present invention can be bent without breakage. In this respect, the minimum bending radius of the thermoelectric element according to the present invention is preferably less than or equal to 50 mm and is more preferably less than or equal to 25 mm.

The minimum bending radius of the thermoelectric element is determined by the procedure that will be described later in relation to Examples.

For example, the thermoelectric element according to the present invention contains a thermoelectric material consisting principally of Fe₃Al, in which case the thermoelectric element is less prone to breakage (cracking) when being bent at 180° with its two opposite end portions in contact with each other.

The procedure for measuring the bending angle of the thermoelectric element is as follows. A 40-millimeter-long piece extending in the longitudinal direction (i.e., a tapping direction in which molten metal is poured in the process of liquid quenching) is cut out of a thermoelectric element. The thermoelectric element piece is then bent in the center of its long sides in such a way as to be creased in the width direction perpendicular to the longitudinal direction. The angle at which the thermoelectric element piece is bent is measured with a protractor, and the measurement value obtained is regarded as the bending angle of the thermoelectric element. The bending angle in a state in which the thermoelectric element is yet to be bent is taken as 0°.

The thermoelectric element according to the present invention is preferably covered with an insulating coating for electrical insulation. The insulating coating needs to be thin so as not to impair the thermal conductivity. It is thus preferable that the insulating coating be an oxide film or contain resin, such as polyimide.

In light of thermal conductivity, the surface roughness of the thermoelectric element according to the present invention is preferably low. For example, the average surface roughness Ra of the thermoelectric element according to the present invention is preferably less than 10 μm.

The procedure for determining the average surface roughness Ra of the thermoelectric element is as follows. Three regions each with a length in a range of 2 to 3 cm are randomly selected in sequence in the longitudinal direction of the thermoelectric element (i.e., in the tapping direction in the process of liquid quenching). Then, the surface roughness Ra of the midsection of each region is measured with a surface roughness measuring machine, such as SJ-210 (manufactured by Mitutoyo Corporation). The mean value of all the measurement values of the surface roughness Ra in the three regions is regarded as the average surface roughness Ra of the thermoelectric element.

[Method for Producing Thermoelectric Element]

A method for producing a thermoelectric element according to the present invention is a method for producing the thermoelectric element according to the present invention through the adoption of liquid quenching. The liquid quenching includes a melt spinning process (single-roll process), a twin-roll process, or a strip casting process. The Euler (Eu) number in the process of producing the thermoelectric element by liquid quenching is in a range of 0.001 to 0.1. The Eu number is given by the expression Eu=ΔP/(ρU²), where ΔP is the pressure (Pa) of molten alloy being tapped, ρ is the density (kg/m³) of a thermoelectric material in a molten state in the process of liquid quenching, and U is the peripheral rotational velocity (m/s) of a quenching roller.

For these features of the thermoelectric element according to the present invention, techniques such as liquid quenching, in-rotating liquid spinning, and solution spinning may be used in the production of the thermoelectric element.

The use of techniques such as liquid quenching, in-rotating liquid spinning, and solution spinning in the production of the thermoelectric element according to the present invention enables an increase in the density of the thermoelectric element and is thus preferred in view to reducing the electrical resistivity of the thermoelectric element and increasing the mechanical strength of the thermoelectric element.

It is especially preferable that liquid quenching be used in the production of the thermoelectric element according to the present invention. The thermoelectric element produced by liquid quenching can be easily formed into a plate (e.g., a thin strip) and is thus easily stuck to an object whose radius of curvature is small. As mentioned above, liquid quenching provides ease of forming the thermoelectric element into a plate (e.g., a thin strip). This means that the thermoelectric element can be easily formed into a shape having a surface contact portion. As a result, the thermoelectric element as a whole becomes highly thermally conductive, and the temperature gradient between two main surfaces opposite to each other in the thickness direction is increased. The thermoelectric element can thus obtain a high thermoelectromotive force.

In the process of liquid quenching, a thermoelectric material prepared as a raw material or, more specifically, a thermoelectric element consisting principally of an intermetallic compound is put into a receptacle, in which the thermoelectric material is melted at high temperatures such that molten alloy (molten metal) is obtained. Examples of the material of the receptacle include ceramic materials and glass containing SiO₂. The receptacle has, in a lower part thereof, a nozzle (a nozzle slit part) that is a tapping portion. The molten alloy obtained is poured out through the nozzle. The molten alloy ejected from the nozzle is rapidly cooled and solidified on contact with a quenching roller that is rotating. That is how the thermoelectric element is formed.

Examples of liquid quenching to be adopted include the melt spinning process (single-roll process), the twin-roll process, and the strip casting process.

The following takes, as an example, the melt spinning process (single-roll process) to describe production conditions in liquid quenching.

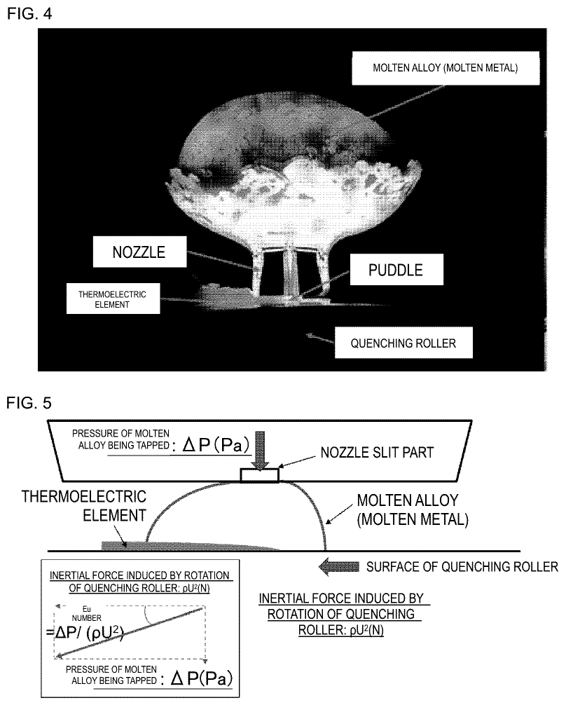

FIG. 3 schematically illustrates an example of how a thermoelectric element is produced by the melt spinning process. FIG. 4 is a photograph showing an example of how a thermoelectric element (consisting principally of Fe₃Al) is produced by the melt spinning process. FIG. 5 is a conceptual diagram for explanation of the Eu number in the melt spinning process.

The Eu number in the process of producing the thermoelectric element according to the present invention by liquid quenching is in the range of 0.001 to 0.1. The Eu number is given by the expression Eu=ΔP/(ρU²), where ΔP is the pressure (Pa) of molten alloy being tapped, ρ is the density (kg/m³) of a thermoelectric material in a molten state in the process of liquid quenching, and U is the peripheral rotational velocity (m/s) of a quenching roller.

The pressure (ΔP) of molten alloy being tapped refers to the pressure exerted on the molten alloy (molten metal) at the tip of the nozzle. A pool of molten alloy formed in a gap between the tip of the nozzle and the quenching roller at which a jet of molten metal is directed is called a puddle. If the pressure of molten alloy being tapped is too low, the puddle would come under increased influence of the inertial force (expressed as ρU², where ρ is the density of the thermoelectric material in a molten state) associated with the peripheral rotational velocity (U) of the quenching roller and would thus be increasingly dragged in a horizontal direction perpendicular to the tapping direction, and consequently, the average thickness of the thermoelectric element obtained would be too small. Furthermore, the molten alloy tapped with such a low pressure would scatter without being formed into a paddle in a stable manner. If the pressure of molten alloy being tapped is too high, the puddle would be pressed too much by the pressure of the molten alloy, and consequently, the average thickness of the thermoelectric element obtained would be too large. Furthermore, the puddle formed by the ejection of the molten alloy tapped with such a high pressure would be crushed out of shape such that the thermoelectric element would not be formed uniformly.

The peripheral rotational velocity of the quenching roller is the circumferential velocity of the quenching roller. If the peripheral rotational velocity of the quenching roller is too low, molten alloy being tapped would be accumulated in relatively large amounts in the form of a puddle whereas the solidified thermoelectric element would be dragged in relatively small amounts in the rotational direction of the roller, and consequently, the thermoelectric element obtained would be thick. If the peripheral rotational velocity of the quenching roller is far too low, the molten alloy would be influenced more by the pressure of molten alloy being tapped than by the inertial force. Consequently, the puddle would be crushed and become unstable, causing the molten alloy to scatter. If the peripheral rotational velocity of the quenching roller is too high, the molten alloy in contact with the quenching roller would be solidified and would then be immediately dragged in the rotational direction of the roller, and consequently, the thermoelectric element obtained would be thin. If the peripheral rotational velocity of the quenching roller is far too high, the molten alloy would be influenced more by the inertial force than by the pressure of molten alloy being tapped. Consequently, the puddle would be dragged by the quenching roller, causing the molten alloy to scatter.

The distance of the gap between the tip of the nozzle and the quenching roller is herein referred to as “nozzle to quenching-roller distance”. If the nozzle to quenching roller distance is too short, the puddle would be more likely to be crushed and become unstable such that the thermoelectric element would not be formed uniformly. Furthermore, if the molten alloy adheres to the tip of the nozzle and comes into contact with the quenching roller, the nozzle would be broken, and as a result, molten alloy would not be discharged out of the nozzle anymore. Consequently, the thermoelectric element would not be formed uniformly. If the nozzle to quenching roller distance is too long, the puddle would not be pushed that hard against the surface of the quenching roller and thus would become unstable. Consequently, the molten alloy would be more likely to scatter. The proper length of the nozzle to quenching roller distance varies depending on the thermoelectric material that is to be formed into molten alloy in the process of liquid quenching.

The various conditions mentioned above may be adjusted in such a manner that the Eu number in the process of producing the thermoelectric element according to the present invention by liquid quenching is in the range of 0.001 to 0.1. This enables the production of a thermoelectric element having an excellent feature in that the thermoelectromotive force caused by the anomalous Nernst effect is high.

If the Eu number in the process of producing the thermoelectric element by liquid quenching is less than 0.001, the inertial force associated with the peripheral rotational velocity of the quenching roller would be too large with respect to the pressure of molten alloy being tapped, and consequently, the average thickness of the thermoelectric element obtained would be too small. If the Eu number in the process of producing the thermoelectric element by liquid quenching is less than 0.001, a pool of molten alloy, namely, a puddle would not be formed in the gap between the tapping portion (i.e., the tip of the nozzle) and the quenching roller, and consequently, the production of the thermoelectric element would become infeasible.

If the Eu number in the process of producing the thermoelectric element by liquid quenching is more than 0.1, the pressure of molten alloy being tapped would be too high with respect to the inertial force associated with the peripheral rotational velocity of the quenching roller, and consequently, the average thickness of the thermoelectric element obtained would be too large. If the Eu number in the process of producing the thermoelectric element by liquid quenching is more than 0.1, molten alloy at the tapping portion (i.e., the tip of the nozzle) would scatter, and consequently, the production of the thermoelectric element would become infeasible.

[Thermoelectric Device]

A thermoelectric device according to the present invention includes the thermoelectric element according to the present invention.

For example, the structure of the thermoelectric device according to the present invention is as follows.

(Example Structure 1)

Example Structure 1 of the thermoelectric device according to the present invention is as follows: two or more sheets each being a thermoelectric element are layered and stuck to each other by welding or soldering or with a conductive adhesive therebetween. The sheets each being a thermoelectric element may be connected to each other by wires or foil made of metal, such as copper and aluminum.

(Example Structure 2)

Example Structure 2 of the thermoelectric device according to the present invention is as follows: a thermoelectric element is wound around a heat source. The thermoelectric element may be wound helically or concentrically around the heat source or may be wound in a shape that is a combination of a helix and concentric circles.

The thermoelectric device according to the present invention may, for example, be a heat flux sensor or an energy harvester.

It is preferable that a terminal for application of voltage be included in the thermoelectric device according to the present invention.

It is also preferable that a heat-dissipating member be included in the thermoelectric device according to the present invention. For example, a heat-dissipating member or, more specifically, a highly thermally conductive sheet for providing adhesion between the thermoelectric element according to the invention and a heating element or any other object to which the thermoelectric element according to the present invention is to be stuck may be disposed between them. This enables an increase in the electromotive voltage generated in the thermoelectric device. With the heating element disposed on one side of the thermoelectric element, the heat-dissipating member may be attached to the reverse side of the thermoelectric device so that the heat-dissipating member can enhance heat transfer with a view to increasing the temperature gradient within the thermoelectric element. This enables a further increase in the electromotive voltage in the thermoelectric device.

[Method for Producing Thermoelectric Device]

A method for producing a thermoelectric device according to the present invention includes the step of producing a thermoelectric element by the method for producing a thermoelectric element according to the present invention.

A method for producing the thermoelectric device described above in relation to Example Structure 1 and a method for producing the thermoelectric device described above in relation to Example Structure 2 are herein taken as examples of the method for producing a thermoelectric device according to the present invention.

(Production Method for Example Structure 1)

A thermoelectric element is produced by the method for producing a thermoelectric element according to the present invention. The thermoelectric element is then cut and formed into sheets. In this way, two or more sheets each being a thermoelectric element are prepared. The sheets each being a thermoelectric element are layered and stuck to each other by welding or soldering or with a conductive adhesive therebetween. In this way, a thermoelectric device including layered sheets each being a thermoelectric element is prepared. When being layered, the sheets each being a thermoelectric element may be connected to each other by wires or foil made of metal, such as copper and aluminum.

(Production Method for Example Structure 2)

A thermoelectric element is produced by the method for producing a thermoelectric element according to the present invention. The thermoelectric element is then wound around a heat source. In this way, a thermoelectric device including a thermoelectric element wound around a heat source is prepared. The thermoelectric element may be wound helically or concentrically around the heat source or may be wound in a shape that is a combination of a helix and concentric circles.

### EXAMPLES

The thermoelectric element according to the present invention is more specifically described below by way of examples. The following examples should not be construed as limiting the scope of the present invention.

### Examples 1 to 9 and Comparative Examples 1 to 7

The following describes procedures by which thermoelectric elements in Examples 1 to 9 and thermoelectric elements in Comparative Examples 1 to 7 were produced.

A reagent was weighed to achieve an atomic percentage ratio of Fe and Al=3:1 or an atomic percentage ratio of Fe and Ga=3:1. The weighed reagent was put into an alumina crucible and was dissolved in an atmosphere of Ar by irradiation with radio-frequency waves emitted from a compact radio-frequency induction furnace VF-HMF500 (manufactured by MAKABE Technical Research Co., Ltd.). The dissolved matter was then poured into a Cu mold, in which the dissolved matter was cooled and solidified, thus being formed into an ingot for use as a raw material of a thermoelectric element. The ingot obtained was pulverized with a jaw crusher.

Subsequently, a plate-like thermoelectric element was produced by the melt spinning process through the use of a liquid quenching machine VF-HMF150 (manufactured by MAKABE Technical Research Co., Ltd.). More specifically, a batch of 20 g of the ingot was put into a slit nozzle made of quartz glass and was dissolved by application of radio-frequency current such that molten alloy (molten metal) was obtained. The examples described herein involved the use of slit nozzles varied in size in accordance with the respective production specifications with a view to obtaining thermoelectric elements whose thicknesses and cross-sectional areas in desired ranges. The temperature of the molten metal was monitored with a radiation thermometer installed on a front surface of the quenching machine. At the instant when the temperature of the molten metal fell within the range of 1,300 to 1,400° C., an Ar gas was sprayed onto the surface of the molten metal at a specified pressure. The molten alloy was poured onto the surface of a quenching copper roller rotating at a predetermined peripheral rotational velocity. This is how a plate-like thermoelectric element was produced. The Eu number in the process of producing the thermoelectric element was as indicated in Table 1.

[Evaluation]

The thermoelectric elements in Examples 1 to 9 and the thermoelectric elements in Comparative Examples 1 to 7 were evaluated for the following features. The results of evaluations are illustrated in Table 1.

<Average Thickness>

Three regions each with a length in a range of 2 to 3 cm were randomly selected in sequence in the longitudinal direction of the thermoelectric element (i.e., in the tapping direction in the melt spinning process). Then, the thickness in the midsection of each region was measured with a micrometer BMS-25MX (manufactured by Mitutoyo Corporation). The mean value of all the measurement values of the thickness in the three regions was regarded as the average thickness of the thermoelectric element.

<Average Cross-Sectional Area>

Three regions each with a length in a range of 2 to 3 cm were randomly selected in sequence in the longitudinal direction of the thermoelectric element (i.e., in the tapping direction in the melt spinning process). Then, the midsection of each region was subjected to image analysis, by which the area of a cross section perpendicular to the longitudinal direction was measured. The mean value of all the measurement values of the cross-sectional areas in the three regions was regarded as the average cross-sectional area in the direction perpendicular to the longitudinal direction of the thermoelectric element.

<Average Crystal Grain Size>

Each of the thermoelectric elements was embedded in resin, and a resultant resin structure was ground into a measurement sample in such a manner that a cross section perpendicular to the longitudinal direction of the thermoelectric element was exposed for measurement. The exposed cross section of the measurement sample was subjected to observation under an optical microscope and a scanning electron microscope (SEM), and images of the cross section perpendicular to the longitudinal direction of the thermoelectric element were taken. Instruments other than the optical microscope and the scanning electron microscope (SEM) may be used for observation of the cross section of the thermoelectric element. The images of the cross section were analyzed by image analysis software, and the crystal grain size, namely, the diameter of each crystal grain within the field of view was measured as the equivalent circle diameter. The mean value of all the measurement values of the crystal grain size was regarded as the average crystal grain size of the thermoelectric material viewed in cross section perpendicular to the longitudinal direction of the thermoelectric element. The average crystal grain size of the thermoelectric material viewed in cross section perpendicular to the longitudinal direction of the thermoelectric element may be a measurement value obtained in accordance with the “testing method for grain size in microstructure of fine ceramics” specified in JIS R1670 or a mean value of multiple calculations based on the linear intercept method and performed for multiple fields of view.

<Minimum Bending Radius>

A cylindrical jig with the outer diameter being adjustable in 1 mm increments and with an allowable surface temperature of 100° C. was prepared. Subsequently, the outer diameter of the jig was set to 100 mm, and the surface temperature of the jig was set to 100° C. In this state, a thermoelectric element sufficiently longer than the outer diameter of the jig was wound around the jig to check whether the thermoelectric element was long enough for one turn around the jig. The occurrence of cracking or breakage of the thermoelectric element was regarded as a sign of the impossibility of winding the thermoelectric element one turn around the jig. The thermoelectric element judged as being able to be wound one turn around the jig was then wound around the jig whose outer diameter was reduced by 1 mm, and a check was made to determine whether the thermoelectric element was long enough for one turn around the jig. Checks were repeatedly conducted in this manner while the outer diameter of the jig was reduced by increments of 1 mm. Once the thermoelectric element was judged as not being able to be wound one turn around the jig, the value obtained by adding 1 mm to the length of the radius (half the diameter) of the jig at the time of the judgement was regarded as the minimum bending radius.

<Thermoelectromotive Force>

The thermoelectromotive force of the thermoelectric element was measured in a state in which the thermoelectric element was stuck to a heating element. A 300-millimeter-long heater with an outside diameter of 25 mm was used as the heating element. The heating element was maintained at 100° C. With the heating element disposed on one side of the thermoelectric element, heat radiated from the reverse side of the thermoelectric element was dissipated into the 25° C. atmosphere. The strength of the external magnetic field was set to 2 T. The anomalous Nernst coefficient of the thermoelectric element under the application of a magnetic field of 2 T was 3 μV/K.

The anomalous Nernst coefficient of the thermoelectric element was measured with a physical property measurement system (PPMS) (manufactured by Quantum Design, Inc.) equipped with the thermal transfer option (TTO). A sample that was 7 millimeters long and about several millimeters in width was fix to a holder. A copper wire plated with gold and measuring 0.1 mm in diameter was used for wiring. The electromotive force of the sample on the holder was measured in the presence of a magnetic field generated by a superconducting magnet and being adjustable over a range of −2 to +2 T (20 Oe/sec). In the course of changing from +2 T to +1 T, the electromotive force was maintained for a duration of 1,200 seconds for every 0.2 T change. In the course of changing from +1 T to −1 T, the electromotive force was maintained for a duration of 1,200 seconds for every 0.1 T change. In the course of changing from −1 T to −2 T, the electromotive force was maintained for a duration of 1,200 seconds for every 0.2 T change.

TABLE 1

| | | | Average | | Minimum | |
|---|---|---|---|---|---|---|
| | Average | Average Cross- | Crystal | | Bending | |
| | Thickness | Sectional Area | Grain Size | Eu | Radius | Thermoelectromotive |
| | (μm) | (mm²) | (μm) | Number | (mm) | Force (mV) |
| Example 1 | 100 | 1 | 100 | 0.1 | 24 | 0.27 |
| Example 2 | 10 | 0.008 | 2 | 0.001 | 23 | 0.26 |
| Example 3 | 95 | 0.95 | 51 | 0.097 | 19 | 0.35 |
| Example 4 | 44 | 0.099 | 38 | 0.011 | 8 | 0.30 |
| Example 5 | 82 | 0.81 | 10 | 0.033 | 20 | 0.37 |
| Example 6 | 22 | 0.022 | 13 | 0.008 | <1 | 0.36 |
| Example 7 | 59 | 0.5 | 22 | 0.014 | 11 | 0.28 |
| Example 8 | 50 | 0.092 | 1.2 | 0.011 | 48 | 0.21 |
| Example 9 | 94 | 0.1 | 129 | 0.1 | 47 | 0.20 |
| Comparative | 7 | 0.103 | 5 | 0.0008 | >50 | not |
| Example 1 | | | | | | evaluable |
| Comparative | 123 | 0.101 | 82 | 0.12 | >50 | not |
| Example 2 | | | | | | evaluable |
| Comparative | 39 | 0.007 | 22 | 0.009 | 15 | 0.18 |
| Example 3 | | | | | | |
| Comparative | 51 | 1.5 | 15 | 0.01 | >50 | not |
| Example 4 | | | | | | evaluable |
| Comparative | 96 | 1.07 | 86 | 0.06 | >50 | not |
| Example 5 | | | | | | evaluable |
| Comparative | not | not | not | 0.0005 | not | not |
| Example 6 | evaluable | evaluable | evaluable | | evaluable | evaluable |
| Comparative | not | not | not | 0.15 | not | not |
| Example 7 | evaluable | evaluable | evaluable | | evaluable | evaluable |

As can be seen in Table 1, evaluations were conducted on the thermoelectric elements in Examples 1 to 9, in which the Eu number in the process of producing the thermoelectric elements by liquid quenching or, more specifically, the melt spinning process was in the range of 0.001 to 0.1. Each of the thermoelectric elements in Examples 1 to 9 involved all of the following features: (1) the thermoelectric element is plate-like in shape; (2) the average thickness of the thermoelectric element is more than or equal to 10 μm and less than or equal to 100 μm; and (3) the average cross-sectional area in the direction perpendicular to the longitudinal direction of the thermoelectric element is more than or equal to 0.008 mm² and less than or equal to 1 mm². The minimum bending radius of each of the thermoelectric elements in Examples 1 to 9 was as small as 50 mm or less. The thermoelectric elements each resisted breakage when being bent at 180°. Furthermore, the thermoelectric elements each had a high thermoelectromotive force. The results reveal that the thermoelectric elements in Examples 1 to 9 each can be stuck to an object with a small radius of curvature and has a high thermoelectromotive force.

The thermoelectric element in Comparative Example 1 had an average thickness of less than 10 μm. With a minimum bending radius of more than 50 mm, the thermoelectric element in Comparative Example 1 was broken during the process of being stuck to a heating element. The measurement of the thermoelectromotive force of the thermoelectric element in Comparative Example 1 was thus not possible.

The thermoelectric element in Comparative Example 2 had an average thickness of more than 100 μm. With a minimum bending radius of more than 50 mm, the thermoelectric element in Comparative Example 2 was broken during the process of being stuck to a heating element. The measurement of the thermoelectromotive force of the thermoelectric element in Comparative Example 2 was thus not possible.

The thermoelectromotive force of the thermoelectric element in Comparative Example 3 with an average cross-sectional area of less than 0.008 mm² in the direction perpendicular to the longitudinal direction of the thermoelectric element was lower than the thermoelectromotive force of any one of the thermoelectric elements in Examples 1 to 9.

The thermoelectric element in Comparative Example 4 had an average cross-sectional area of more than 1 mm² in the direction perpendicular to the longitudinal direction of the thermoelectric element. With a minimum bending radius of more than 50 mm, the thermoelectric element was broken during the process of being stuck to a heating element. The measurement of the thermoelectromotive force of the thermoelectric element in Comparative Example 4 was thus not possible.

The thermoelectric element in Comparative Example 5 had an average cross-sectional area of more than 1 mm² in the direction perpendicular to the longitudinal direction of the thermoelectric element. With a minimum bending radius of more than 50 mm, the thermoelectric element was broken during the process of being stuck to a heating element. The measurement of the thermoelectromotive force of the thermoelectric element in Comparative Example 5 was thus not possible.

In Comparative Example 6, an attempt was made to produce a thermoelectric element in such a manner that the Eu number in the process of producing the thermoelectric element by liquid quenching or, more specifically, the melt spinning process was much less than 0.001; however, the production of such a thermoelectric element was not possible.

In Comparative Example 7, an attempt was made to produce a thermoelectric element in such a manner that the Eu number in the process of producing the thermoelectric element by liquid quenching or, more specifically, the melt spinning process was much more than 0.1; however, the production of such a thermoelectric element was not possible.

Although the liquid quenching adopted in the production of the thermoelectric elements in the examples mentioned above was the melt spinning process (single-roll process), the properties of thermoelectric elements produced by another liquid quenching technique such as the twin-roll process or the strip casting process were confirmed to be comparable to those described above as the results of evaluations.

1. A thermoelectric element comprising:
a plate shaped thermoelectric material that exhibits an anomalous Nernst effect, the thermoelectric element having an average thickness of 10 μm to 100 μm, and an average cross-sectional area of 0.008 mm² to 1 mm² as measured in a cross section perpendicular to a longitudinal direction of the thermoelectric element.

2. The thermoelectric element according to claim 1, wherein an average crystal grain size of the thermoelectric material is 2 μm to 100 μm as measured in the cross section perpendicular to the longitudinal direction of the thermoelectric element.

3. The thermoelectric element according to claim 1, wherein the thermoelectric material is selected from Fe₃Al, Fe₃Ga, Mn₃Sn, Mn₃Ga, Co₂MnGa, Co₂MnAl, Co₂MnIn, Mn₃Ge, Fe₂NiGa, CoTiSb, CoVSb, CoCrSb, CoMnSb, or TiGa₂Mn.

4. The thermoelectric element according to claim 1, wherein the thermoelectric material consists principally of an intermetallic compound having a chemical formula of Fe₃Al, Fe₃Ga, Mn₃Sn, Mn₃Ga, Co₂MnGa, Co₂MnAl, Co₂MnIn, Mn₃Ge, Fe₂NiGa, CoTiSb, CoVSb, CoCrSb, CoMnSb, or TiGa₂Mn.

5. The thermoelectric element according to claim 1, wherein the thermoelectric material contains an intermetallic compound in an ordered phase.

6. The thermoelectric element according to claim 1, wherein the thermoelectric element consists principally of a Weyl magnetic substance.

7. The thermoelectric element according to claim 1, wherein a minimum bending radius of the thermoelectric element is less than or equal to 50 mm.

8. The thermoelectric element according to claim 1, wherein an average surface roughness of the thermoelectric element is less than 10 μm.

9. A method for producing a thermoelectric element, the method comprising:
melting a thermoelectric material comprising an intermetallic compound in a receptacle to obtain a molten alloy; and
performing a liquid quenching of the molten material by ejecting the molten alloy from the receptacle onto a rotating quenching roller so as to cool and solidify the molten material and form the thermoelectric element having an average thickness of 10 μm to 100 μm, and an average cross-sectional area of 0.008 mm² to 1 mm² as measured in a cross section perpendicular to a longitudinal direction of the thermoelectric element,
wherein, the liquid quenching is conducted with a Euler (Eu) number in a range of 0.001 to 0.1, the Eu number being given by an expression Eu=ΔP/(ρU²),
where
ΔP is a pressure of the molten alloy being ejected,
ρ is a density (kg/m³) of the molten material, and
U is peripheral rotational velocity (m/s) of the quenching roller.

10. The method for producing the thermoelectric element according to claim 9, wherein the liquid quenching includes a single-roll melt spinning process, a twin-roll melt spinning process, or a strip casting process.

11. A thermoelectric device comprising:
a heat source; and
the thermoelectric element according to claim 1 wound around the heat source.

12. The thermoelectric device according to claim 11, wherein an average crystal grain size of the thermoelectric material is 2 μm to 100 μm as measured in the cross section perpendicular to the longitudinal direction of the thermoelectric element.

13. The thermoelectric device according to claim 11, wherein the thermoelectric material is selected from Fe₃Al, Fe₃Ga, Mn₃Sn, Mn₃Ga, Co₂MnGa, Co₂MnAl, Co₂MnIn, Mn₃Ge, Fe₂NiGa, CoTiSb, CoVSb, CoCrSb, CoMnSb, or TiGa₂Mn.

14. The thermoelectric device according to claim 11, wherein the thermoelectric material consists principally of an intermetallic compound having a chemical formula of Fe₃Al, Fe₃Ga, Mn₃Sn, Mn₃Ga, Co₂MnGa, Co₂MnAl, Co₂MnIn, Mn₃Ge, Fe₂NiGa, CoTiSb, CoVSb, CoCrSb, CoMnSb, or TiGa₂Mn.

15. The thermoelectric device according to claim 11, wherein the thermoelectric material contains an intermetallic compound in an ordered phase.

16. The thermoelectric device according to claim 11, wherein the thermoelectric element consists principally of a Weyl magnetic substance.

17. The thermoelectric device according to claim 11, wherein a minimum bending radius of the thermoelectric element is less than or equal to 50 mm.

18. The thermoelectric device according to claim 11, wherein an average surface roughness of the thermoelectric element is less than 10 μm.

19. A method for producing a thermoelectric device, the method comprising:
producing the thermoelectric element according to claim 9; and
winding the thermoelectric element around a heat source.
